(19) United States
(12) Patent Application Publication
(10) Pub. No.: US 2026/0104437 A1
(43) Pub. Date: Apr. 16, 2026

(54) PROBE FOR PROBE CARD

(71) Applicant: JAPAN ELECTRONIC MATERIALS CORPORATION, Amagasaki-shi, Hyogo (JP)

(72) Inventor: Noriyuki FUKUSHIMA, Amagasaki-shi, Hyogo (JP)

(73) Assignee: JAPAN ELECTRONIC MATERIALS CORPORATION, Amagasaki-shi, Hyogo (JP)

(21) Appl. No.: 19/113,783

(22) PCT Filed: Sep. 21, 2022
(86) PCT No.: PCT/JP2022/035190

§ 371 Date: Mar. 20, 2025

(51) Int. Cl. G01R 1/073; G01R 1/067

(52) U.S. Cl. CPC G01R 1/07342; G01R 1/06716; G01R 1/06761

(57) ABSTRACT

A probe for a probe card includes: a plurality of deformed regions, which are provided in two rows in at least one side surface among two side surfaces that are each perpendicular to two planes that are perpendicular to a buckling direction of the probe, the plurality of deformed regions being recesses relative to the side surface, each row being constituted by a plurality of the deformed regions arranged with intervals therebetween in a lengthwise direction of the probe, and the two rows being spaced apart from each other; and a framework region having a zigzag shape between the two rows of the plurality of deformed regions, wherein a length of the framework region is greater than a length of the probe in the lengthwise direction.

### TECHNICAL FIELD

The present disclosure relates to a probe for a probe card.

### BACKGROUND ART

A probe card is an electrical connection device used to supply power, input and output signals, and provide grounding by bringing probes into contact with electrode pads of semiconductor devices in order to perform operational testing of individual semiconductor devices formed on a wafer.

Probes are provided on a surface of the probe card and are configured such that tips thereof are pressed against electrode pads of semiconductor devices with a predetermined pressing force.

In order to increase the number of semiconductor devices formed on a wafer, it is necessary to reduce the size of the semiconductor devices. Therefore, electrode pads of semiconductor devices are designed to be smaller, and the distance (pitch) between the electrode pads is also designed to be smaller.

Accordingly, it becomes necessary to miniaturize the probes in accordance with the miniaturization of semiconductor devices. However, when the probes are miniaturized, there arises a problem in that the mechanical strength thereof decreases.

Therefore, in order to ensure good electrical and mechanical contact with the electrode pads of semiconductor devices, for example, Patent Document 1 proposes a configuration in which a multilayer metal sheet is used for the probe.

### CITATION LIST

### Patent Document

[Patent Document 1] Japanese Laid-open Patent Publication No. 2018-501490

### SUMMARY OF THE INVENTION

### Problem to be Solved by the Invention

The probe disclosed in Patent Document 1 is a contact probe having at least one multilayer structure including a core and a first inner coating layer laminated thereon, and an outer coating layer made of a material having higher hardness than the core, which completely covers the multilayer structure.

As disclosed in Patent Document 1, in order to achieve good electrical and mechanical contact, it is preferable to adopt a configuration in which multiple layers of different materials are laminated. However, there is a limit to meeting the demand of making the cross-sectional thickness of the probe thinner, and thus further breakthroughs have been required.

In an inspection process using a probe card, in order to ensure contact with the electrode pads of semiconductor devices, after the probes make contact with the electrode pads, the probe card is brought still closer to the semiconductor wafer (overdrive), thereby pressing the probes against the electrode pads of the semiconductor devices.

Accordingly, the probes are required to have sufficient strength so as not to be destroyed mechanically even when a contact pressure exceeding a predetermined value is applied. To prevent the probes from damage, it is necessary to prevent localized stress concentration in the probes. Consequently, probes having surfaces that are as smooth and scratch-free as possible have been demanded to prevent such stress concentration.

However, there is a limit to how smooth a metal surface can be made, and the thinner the cross-sectional thickness of the probe, the more easily it deforms under external force (i.e., the lower its mechanical strength).

The present disclosure provides a technology to solve the aforementioned problems. An object of the present disclosure is to provide a probe that, even if miniaturized, can contact the electrode pads of semiconductor devices with an appropriate contact pressure (needle pressure) and still have sufficient strength to avoid damage even when a contact pressure exceeding a predetermined value is applied.

In other words, the probe for a probe card according to the present disclosure aims to provide a probe for a probe card capable of withstanding large stresses (i.e., having high mechanical strength) by intentionally distributing the positions at which stress concentration occurs, rather than attempting to prevent stress concentration itself.

### Means to Solve the Problem

A probe for a probe card disclosed in the present disclosure includes: a plurality of deformed regions, which are provided in two rows in at least one side surface among two side surfaces that are each perpendicular to two planes that are perpendicular to a buckling direction of the probe, the plurality of deformed regions being recesses relative to the side surface, each row being constituted by a plurality of the deformed regions arranged with intervals therebetween in a lengthwise direction of the probe, and the two rows being spaced apart from each other; and a framework region having a zigzag shape between the two rows of the plurality of deformed regions, wherein a length of the framework region is greater than a length of the probe in the lengthwise direction.

### Effect of the Invention

According to the probe for a probe card disclosed in the present disclosure, even if the plate thickness is reduced, it is possible to provide a probe for a probe card with high mechanical strength by dispersing the locations at which stress concentration occurs.

### BRIEF DESCRIPTION OF THE DRAWINGS

FIG. 1 is a diagram schematically showing a state in which an electronic circuit is inspected by a probe card according to Embodiment 1.

FIG. 2 is a perspective view of a probe according to Embodiment 1.

FIG. 3 is a cross-sectional view taken along line A-A in FIG. 2 and is a cross-sectional view perpendicular to the lengthwise direction of the probe.

FIG. 4 is a diagram showing the positional relationship of two rows of deformed regions according to Embodiment 1.

FIG. 5 is a cross-sectional view showing a modified example of the probe according to Embodiment 1.

FIG. 6 is a cross-sectional view perpendicular to the lengthwise direction of a probe according to Embodiment 2.

FIG. 7 is a cross-sectional view perpendicular to the lengthwise direction of a probe according to Embodiment 3.

FIG. 8 is a cross-sectional view showing a modified example of the probe according to Embodiment 3.

FIG. 9A is a diagram showing a variation of the deformed regions according to Embodiment 4.

FIG. 9B is a diagram showing a variation of the deformed regions according to Embodiment 4.

FIG. 9C is a diagram showing a variation of the deformed regions according to Embodiment 4.

FIG. 10A is a diagram showing a variation of the deformed regions according to Embodiment 5.

FIG. 10B is a diagram showing a variation of the deformed regions according to Embodiment 5.

FIG. 10C is a diagram showing a variation of the deformed regions according to Embodiment 5.

FIG. 11 is a diagram showing a variation of the deformed regions according to Embodiment 5.

### DESCRIPTION OF EMBODIMENTS

### Embodiment 1

A probe for a probe card according to Embodiment 1 will be described below with reference to the drawings.

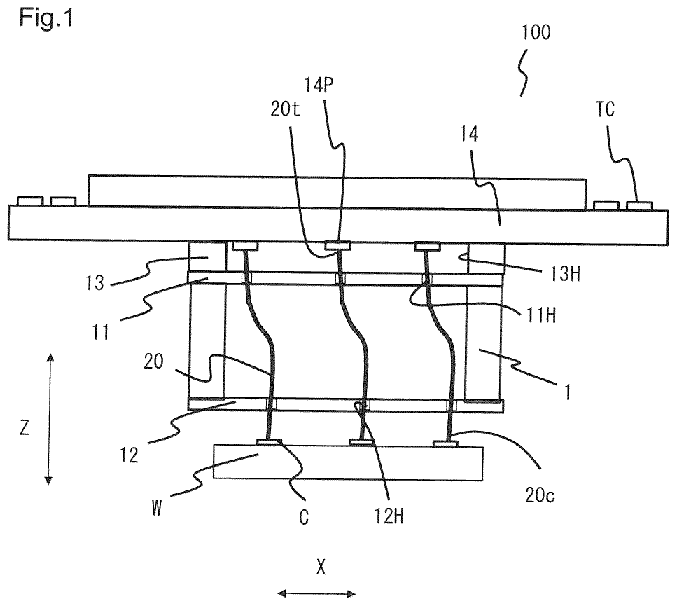

FIG. 1 is a diagram schematically showing a state in which an electronic circuit is inspected by a probe card 100.

In the present specification, the upper side of FIG. 1 is referred to as “up,” and the lower side thereof is referred to as “down.” That is, seen from a probe card 100, the side for inspection target is referred to as “down.” Furthermore, the left-right direction of FIG. 1 is referred to as buckling direction X, and the front-back direction extending from the front side of FIG. 1 to the back side is referred to as direction Y, which is perpendicular to buckling direction X. In addition, the vertical direction of FIG. 1, which is the lengthwise direction of a probe 20, is referred to as lengthwise direction Z.

Probe card 100 is a device used to inspect electrical characteristics of an electronic circuit formed on a semiconductor wafer W. Probe card 100 is provided with a large number of probes 20 that respectively contact electrodes C of the electronic circuit formed on semiconductor wafer W. Characteristic inspection of the electronic circuit is performed by bringing semiconductor wafer W close to probe card 100 so that the tip of probe 20 contacts electrode C on the electronic circuit, and establishing conduction between a tester device (not shown) and a tester connection electrode TC on wiring board 14 of probe card 100 via probe 20.

Probe card 100 comprises a hollow frame 1, an upper guide 11 attached to an upper end of frame 1, a lower guide 12 attached to a lower end of frame 1, a fixing plate 13 for fixing upper guide 11, and wiring board 14. An intermediate guide may be provided further between upper guide 11 and lower guide 12.

Upper guide 11 has a plurality of guide holes 11H extending vertically therethrough, and lower guide 12, disposed below upper guide 11, also has a plurality of guide holes 12H extending vertically therethrough. An opening 13H formed in fixing plate 13 is located above the group of guide holes 11H of upper guide 11. Wiring board 14 is disposed on an upper surface of fixing plate 13. A plurality of probe connection pads 14P, which come into contact with terminal sections 20t at upper ends of probes 20, are formed on a lower surface of wiring board 14.

A plurality of probes 20 are inserted and guided such that each probe 20 passes through guide holes 12H and guide holes 11H. Probe 20 is a so-called vertical-type probe arranged approximately perpendicular to the target of inspection (the electronic circuit formed on semiconductor wafer W).

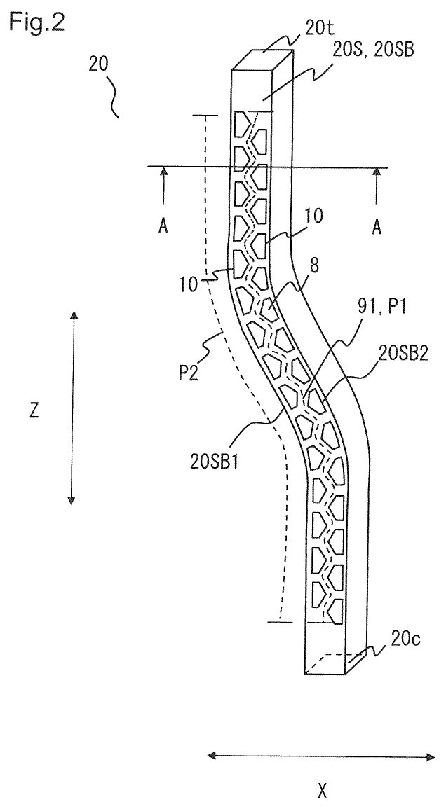

FIG. 2 is a perspective view of probe 20. The left-right direction in FIG. 2 corresponds to buckling direction X of probe 20, namely the direction in which probe 20 elastically deforms at the time of overdrive of probe card 100. Probe 20 has an elongated shape, with a central portion that is curved and upper and lower portions that extend vertically in a linear shape. A contact portion 20c is provided at a lower end (one end) of probe 20, and a terminal section 20t is formed at an upper end (the other end).

When overdrive is performed, probe 20 buckles in buckling direction X according to reactive force from the target of inspection, owing to compression in lengthwise direction Z. Contact portion 20c moves toward terminal section 20t, thereby generating stress within probe 20.

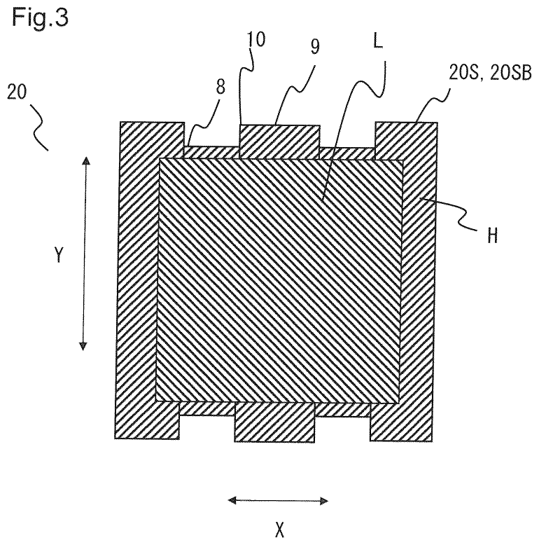

FIG. 3 is a cross-sectional view taken along line A-A in FIG. 2, which is perpendicular to lengthwise direction Z of probe 20. The left-right direction in FIG. 3 is buckling direction X.

Probe 20 is formed of two types of metals having conductivity and different resistivities. One is an inner metal (a first metal) that forms low-resistance section L, made of, for example, copper, gold, or silver (Cu, Au, Ag) with low resistivity. Low-resistance section L provides high conductivity and improves current-carrying performance. The other is an outer metal (a second metal) that forms high-resistance section H, made of a material such as palladium-cobalt (PdCo) alloy, which has higher resistivity and lower conductivity than low-resistance section L but offers higher mechanical strength and spring properties. High-resistance section H functions to maintain the mechanical strength of probe 20.

As shown in FIG. 3, a plurality of deformed regions 8 and a framework region 9 are formed on side surfaces 20S of high-resistance section H of probe 20, the side surfaces 20S being perpendicular to two planes each perpendicular to buckling direction X. Each deformed region 8 is a region in which an original reference surface 20SB, which was a flat plane of the probe card, is deformed so as to form a recess. Framework region 9 is a region that connects among a plurality of deformed regions 8. The boundary between deformed region 8 and framework region 9 is referred to as ridge 10.

FIGS. 2 and 3 show an example in which multiple pentagonal-prism-shaped recesses are formed as deformed regions 8 in reference surface 20SB, which was originally flat. Framework region 9 is the planar portion between deformed regions 8. Multiple pentagonal-prism-shaped deformed regions 8 are provided in two rows along lengthwise direction Z of probe 20, and each row is arranged such that ridges 10 of multiple deformed regions 8 align in the lengthwise direction at both ends of side surface 20S in buckling direction X.

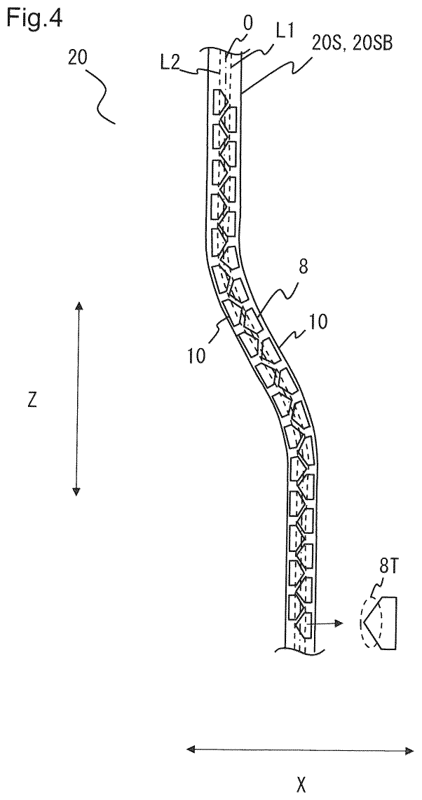

FIG. 4 is a side view of probe 20, showing the positional relationship of two rows of deformed regions 8. The two rows of deformed regions 8 are arranged so that their positions in lengthwise direction Z of probe 20 are staggered.

In two rows adjacent in buckling direction X (here, two rows), the pentagonal-prism shapes of the respective deformed regions 8 are reversed relative to buckling direction X. Further, in FIG. 4, dashed line L1, which connects the right ends of the deformed regions 8 in the left row, is located to the right of central line O in buckling direction X of side surface 20S, and dashed line L2, which connects the left ends of the deformed regions 8 in the right row, is located to the left of central line O in buckling direction X of side surface 20S.

By arranging the deformed regions 8 in each row in this manner, side surface 20S of high-resistance section H of probe 20 is provided, as shown in FIG. 2, with side beams 20SB1 and 20SB2 that extend in lengthwise direction Z at both sides in buckling direction X. In addition, a framework region 91 extending in lengthwise direction Z in a zigzag shape is formed in the center of side surface 20S of probe 20, between the two rows of deformed regions 8. The length P1 of this framework region 91 is longer than the length P2 in lengthwise direction Z of the portion of probe 20 where deformed regions 8 are formed, i.e., longer than the length of side beams 20SB1 and 20SB2.

Hence, if it is assumed that two deformed regions 8 adjacent in buckling direction X (belonging to different rows) are viewed in the lengthwise direction Z of probe 20, portions of each deformed region 8 (protrusions 8T in buckling direction X) appear to overlap one another.

When comparing a probe A having no deformed regions 8 with a probe 20 provided with deformed regions 8 on both front and back surfaces, the relationship between overdrive amount and needle pressure reveals that probe 20 having deformed regions 8 exhibits a lower needle pressure.

Additionally, an analysis was conducted to ascertain the effect of deformed regions 8. FEM (Finite Element Method) analysis was performed to compute the maximum stress on probe A (with no recesses and a smooth surface) and probe 20 (with pentagonal-prism-shaped recesses). The results indicated that, when an external force is applied, stress concentrates on ridges 10 at boundaries between deformed regions 8 and framework region 9. It was also discovered that making the bottom surfaces of deformed regions 8 planar leads to stress concentration on ridges 10 at the boundaries between deformed regions 8 and framework region 9.

This suggests that, when deformed regions 8 are formed as polygonal-prism recesses, stress concentration occurs at each vertex of the polygon. Accordingly, when an external force is applied, stress is dispersed among those vertices.

Thus, by arranging deformed regions 8 in high-resistance section H, which contributes to maintaining the mechanical strength of probe 20, the length of framework region 91 can be extended, stress concentration points can be distributed, and the needle pressure of probe 20 can be reduced.

Probe 20 is manufactured using so-called MEMS (Micro Electro Mechanical Systems) technology (a probe intermediate formation process). MEMS technology is a technology for forming fine three-dimensional structures by utilizing photolithography and sacrificial layer etching. Photolithography is a micro-pattern processing technology using photoresists, commonly applied in semiconductor manufacturing. Sacrificial layer etching is a technology in which a lower sacrificial layer is formed, the structural layers are built thereon, and only the sacrificial layer is removed by etching, thereby creating a three-dimensional structure.

A known plating technology can be utilized for forming each layer. For example, immersing a substrate serving as a cathode and a piece of metal serving as an anode in electrolytic solution and applying voltage therebetween enables metal ions in the electrolytic solution to adhere to the substrate surface. Such a process is referred to as electroplating, which is a wet process where the substrate is immersed in the electrolytic solution. After the plating process, a drying process is carried out to obtain an intermediate body of the probe. Furthermore, after this drying process, the lower tip portion is subjected to a polishing process (a polishing step) to form contact portion 20c.

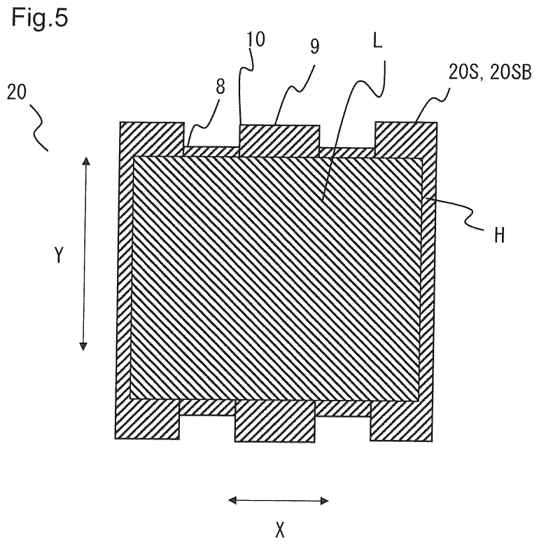

FIG. 5 is a cross-sectional view showing a modified example of probe 20. As shown in the figure, the thickness of high-resistance section H on the side where no deformed regions 8 are provided may be made smaller than that on side surface 20S where deformed regions 8 are provided. In this case, the electrical resistance of the probe can be reduced.

According to the probe for a probe card of Embodiment 1, by arranging deformed regions 8 in high-resistance section H, which helps maintain the mechanical strength of probe 20, it is possible to extend the length of framework region 91, distribute stress concentration points, and reduce needle pressure. If the same needle pressure is retained, the overall length of probe 20 can be shortened. Note that there may be three or more rows of deformed regions 8, and deformed regions 8 may be disposed on only one side surface 20S.

### Embodiment 2

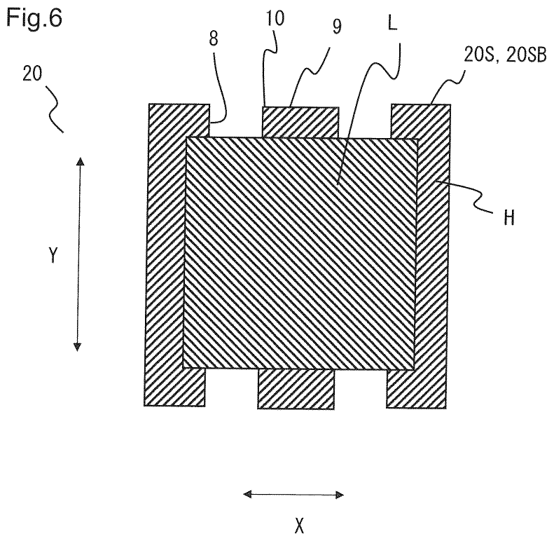

Hereinafter, a probe for a probe card according to Embodiment 2 will be described, focusing on aspects that differ from Embodiment 1. In the present embodiment, a modified example of deformed regions 8 is described. FIG. 6 is a cross-sectional view perpendicular to the lengthwise direction of a probe 20 according to Embodiment 2. The left-right direction therein is buckling direction X. Unlike Embodiment 1, high-resistance section H having spring properties penetrates as far as low-resistance section L, which has lower electrical resistance.

In Embodiment 1, deformed regions 8 did not penetrate high-resistance section H. In the present Embodiment 2, deformed regions 8 penetrate high-resistance section H, and low-resistance section L is visible from side surface 20S of probe 20. With this configuration, framework region 91 can exhibit further elasticity, thereby further reducing needle pressure.

### Embodiment 3

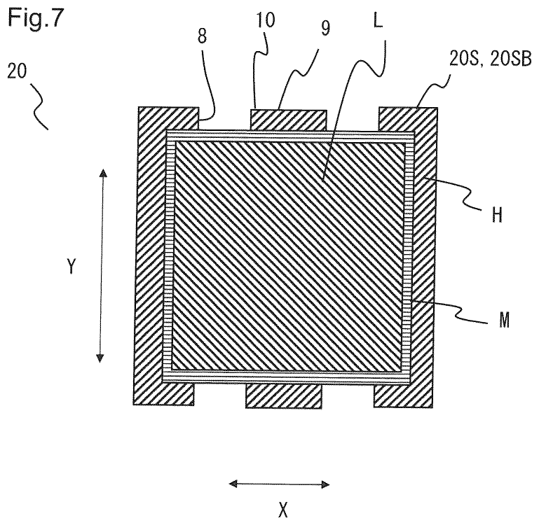

Hereinafter, a probe for a probe card according to Embodiment 3 will be described, focusing on aspects different from Embodiment 2. In the present embodiment, a modified example of deformed regions 8 is explained. FIG. 7 is a cross-sectional view perpendicular to the lengthwise direction of a probe according to Embodiment 3. As in Embodiment 2, in the present Embodiment 3, deformed regions 8 penetrate high-resistance section H. Moreover, in Embodiment 3, an intermediate layer M (third metal layer) is provided between high-resistance section H and low-resistance section L. Deformed regions 8 are not formed in intermediate layer M.

In Embodiment 2, if the exposed low-resistance section L must be of a material that does not melt during sacrificial layer etching, the present Embodiment 3 broadens the range of potential materials for low-resistance section L by providing intermediate layer M, which does not melt during sacrificial layer etching, so that low-resistance section L is protected from melting. A material such as Pd or Pt, which does not melt during sacrificial layer etching and has a relatively low Young's modulus (thus producing minimal stress upon deformation), can be used as intermediate layer M. Depending on the required needle pressure and the length of probe 20, providing intermediate layer M is advisable.

According to the probe for a probe card of Embodiment 2, by broadening the range of selectable materials for low-resistance section L, a probe can be realized that possesses even lower electrical resistance than that in Embodiment 2 and exhibits even greater elasticity than that in Embodiment 1.

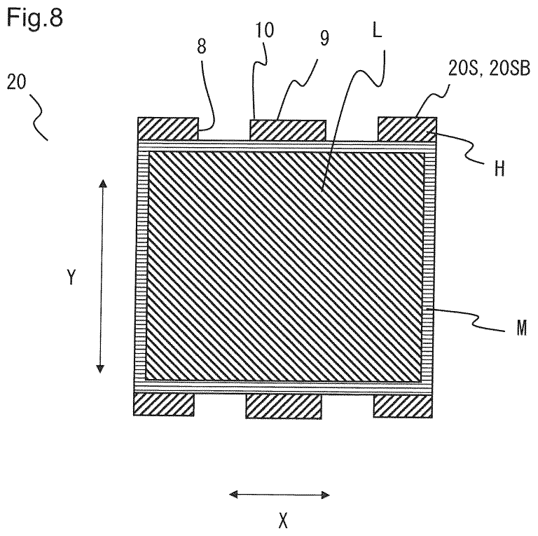

FIG. 8 is a cross-sectional view showing a modified example of probe 20. As shown in FIG. 8, high-resistance section H may be provided solely on side surface 20S where deformed regions 8 are formed. In this case, when metal layers are formed in direction Y by MEMS, the number of steps can be reduced.

### Embodiment 4

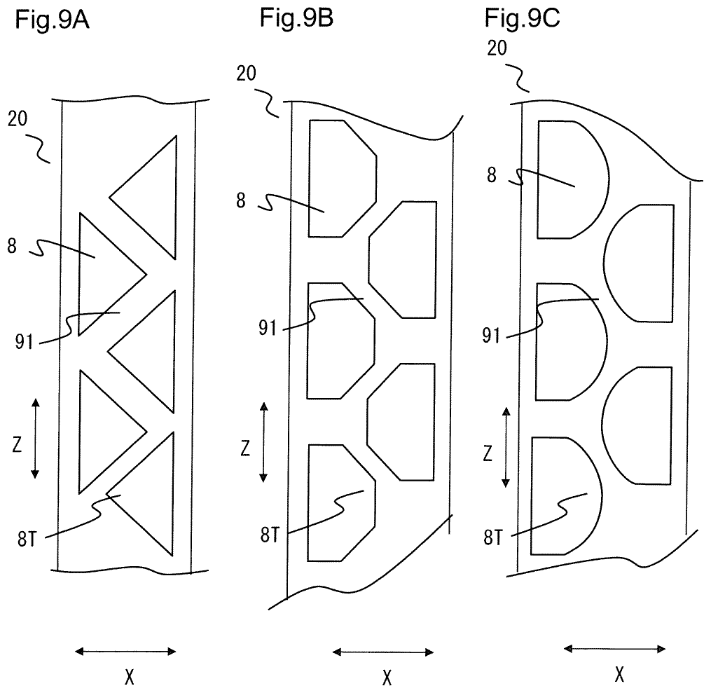

A probe for a probe card according to Embodiment 4 will now be described with reference to the drawings. In the present embodiment, other examples of deformed regions 8 are described. FIGS. 9A through 9C show variations of deformed regions 8. As shown in FIG. 9A, triangular-prism deformed regions 8 may be arranged in two rows along lengthwise direction Z of probe 20, reversed alternately in buckling direction X so as to protrude toward the center of side surface 20S.

Additionally, as shown in FIG. 9B, when viewed in buckling direction X, hexagonal-prism-shaped deformed regions 8 that have two sides parallel to buckling direction X and two sides parallel to lengthwise direction Z may be arranged in two rows along lengthwise direction Z of probe 20, reversed alternately in buckling direction X.

Furthermore, as shown in FIG. 9C, half-cylindrical triangular-prism deformed regions 8 shaped like a semicylindrical may be arranged in two rows along lengthwise direction Z of probe 20 so as to protrude alternately toward the center of side surface 20S in a reversed manner relative to buckling direction X. In any case, the tip of each deformed region protruding in buckling direction X must be located beyond central line O of side surface 20S in buckling direction X, as in Embodiment 1. This provides the same effects as in Embodiment 1.

Embodiment 5

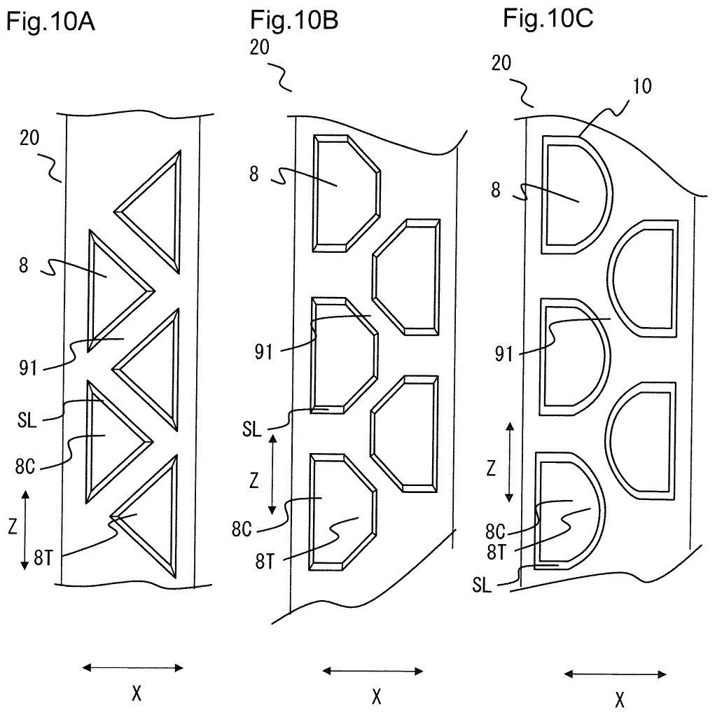

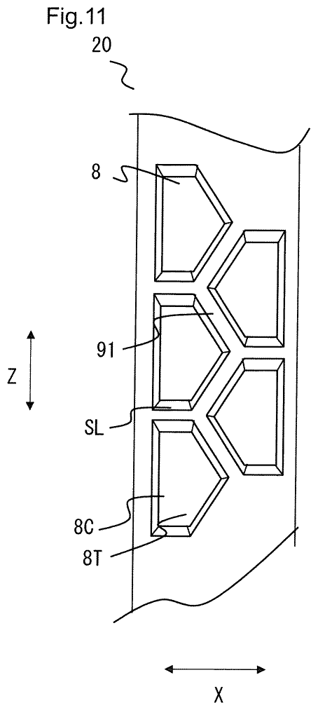

Hereinafter, a probe for a probe card according to Embodiment 5 will be described with reference to the drawings. In the present embodiment, further examples of deformed regions 8 are described. FIGS. 10A, 10B, 10C, and 11 show variations of deformed regions 8. As illustrated in FIG. 10A, deformed regions 8 may be frustum-shaped triangular pyramids; as shown in FIG. 10B, they may be frustum-shaped pentagonal pyramids; or, as shown in FIG. 10C, they may have a bottom surface that is similar in shape to ridge 10 of deformed region 8 but smaller, such as a semicylindrical-arch shape. That is, in each deformed region 8, a central portion 8C is a flat surface, and the peripheral portion of central portion 8C is an inclined surface SL that expands toward side surface 20S. By making the width of framework region 91 gradually increase toward the central portion 8C, the strength of framework region 91 is enhanced. The probe for a probe card according to Embodiment 5 also provides effects similar to those of Embodiments 1 through 4.

Although the disclosure is described above in terms of various exemplary embodiments and implementations, it should be understood that the various features, aspects, and functionality described in one or more of the individual embodiments are not limited in their applicability to the particular embodiment with which they are described, but they can be applied, alone or in various combinations to one or more of the embodiments of the disclosure.

It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

100 probe card
1 frame
10 ridge
11 upper guide
11H guide hole
12 lower guide
12H guide hole
13 fixing plate
13H opening
14 wiring board
14P probe connection pad
20 probe
20c contact portion
20SB1, 20SB2 side beams
20m central portion
20S side surface
20SB reference surface
20t terminal section
8 deformed region
8T protrusion
9, 91 framework region
C electrode
H high-resistance section
L low-resistance section
M intermediate layer
O central line
TC tester connection electrode
W semiconductor wafer
P1, P2 length
8C central portion
SL inclined surface
X buckling direction
Y direction perpendicular to buckling direction X
Z lengthwise direction

1. A probe for a probe card, wherein
the probe includes:
a plurality of deformed regions, which are provided in two rows in at least one side surface among two side surfaces that are each perpendicular to two planes that are perpendicular to a buckling direction of the probe, the plurality of deformed regions being recesses relative to the side surface, each row being constituted by a plurality of the deformed regions arranged with intervals therebetween in a lengthwise direction of the probe, and the two rows being spaced apart from each other; and
a framework region having a zigzag shape between the two rows of the plurality of deformed regions, wherein
a length of the framework region is greater than a length of the probe in the lengthwise direction.

2. The probe for a probe card according to claim 1, wherein,
if two deformed regions adjacent in the buckling direction are viewed in the lengthwise direction of the probe), partial regions of the two deformed regions overlap one another in appearance.

3. The probe for a probe card according to claim 1, wherein
two deformed regions adjacent in the buckling direction have shapes reversed relative to the buckling direction.

4. The probe for a probe card according to claim 1, wherein
each deformed region is any of a triangular shape, a pentagonal shape, a hexagonal shape, or a semicylindrical-arch shape, and in the two rows adjacent to each other, a deformed region in one row has a protrusion projecting toward the other row.

5. The probe for a probe card according to claim 1, wherein each deformed region has a bottom surface that is a flat plane, and a peripheral portion thereof is an inclined surface sloping so as to expand toward the side surface.

6. The probe for a probe card according to claim 1, wherein
the probe comprises:
an inner first metal layer having low electrical resistance; and
an outer second metal layer that is harder than the first metal layer and has spring properties, and
the deformed regions are formed in the second metal layer.

7. The probe for a probe card according to claim 6, Wherein
the deformed regions penetrate through the second metal layer.

8. The probe for a probe card according to claim 7, Wherein
a third metal layer is provided between the first metal layer and the second metal layer.

9. The probe for a probe card according to claim 2, wherein
the probe comprises:
an inner first metal layer having low electrical resistance; and
an outer second metal layer that is harder than the first metal layer and has spring properties, and
the deformed regions are formed in the second metal layer.

10. The probe for a probe card according to claim 3, wherein
the probe comprises:
an inner first metal layer having low electrical resistance; and
an outer second metal layer that is harder than the first metal layer and has spring properties, and
the deformed regions are formed in the second metal layer.

11. The probe for a probe card according to claim 4, wherein
the probe comprises:
an inner first metal layer having low electrical resistance; and
an outer second metal layer that is harder than the first metal layer and has spring properties, and
the deformed regions are formed in the second metal layer.

12. The probe for a probe card according to claim 5, wherein
the probe comprises:
an inner first metal layer having low electrical resistance; and
an outer second metal layer that is harder than the first metal layer and has spring properties, and
the deformed regions are formed in the second metal layer.
